(19) United States
(12) Patent Application Publication
(10) Pub. No.: US 2025/0212392 A1
(43) Pub. Date: Jun. 26, 2025

(54) SEMICONDUCTOR MEMORY DEVICE

(71) Applicant: SAMSUNG ELECTRONICS CO., LTD., Suwon-si (KR)

(72) Inventor: Jinbum Kim, Suwon-si (KR)

(21) Appl. No.: 18/777,978

(22) Filed: Jul. 19, 2024

(30) Foreign Application Priority Data
Dec. 20, 2023 (KR) 10-2023-0187521

(51) Int. Cl. H10B 12/00

(52) U.S. Cl. CPC H10B 12/34; H10B 12/053; H10B 12/315

(57) ABSTRACT

A semiconductor memory device includes a conductive line elongated in a first direction, a superlattice layer disposed on the conductive line, a plurality of channel areas spaced apart from each other in the first direction on the superlattice layer and each connected to the conductive line, a back-gate electrode elongated in a second direction between a first channel area and a second channel area, and a pair of word lines arranged between the second channel area and a third channel area. The superlattice layer includes a first superlattice layer having a plurality of first oxide layers and a plurality of first compound layers that are alternately stacked on each other. The superlattice layer includes a second superlattice layer having a plurality of second oxide layers and a plurality of second compound layers that are alternately stacked on each other.

### CROSS-REFERENCE TO RELATED APPLICATION

This application claims priority under 35 U.S.C. § 119 to Korean Patent Application No. 10-2023-0187521, filed on Dec. 20, 2023, in the Korean Intellectual Property Office, the disclosure of which is incorporated by reference herein in its entirety.

### BACKGROUND

Most semiconductor apparatuses include transistors. For example, in memory apparatuses such as dynamic random-access memory (DRAM), a memory cell includes a cell transistor.

Because memory devices continue to require improvements in integration and performance, transistor manufacturing technology faces physical limitations. For example, as a size of a memory cell decreases, a size of a transistor decreases, which inevitably reduces a channel length of the transistor. When the channel length of the transistor decreases, characteristics of the memory device deteriorate due to various problems such as decreased data retention characteristics.

Recently, vertical channel transistors have been proposed. A vertical channel transistor (VCT) includes a pillar in which a vertical channel is formed.

### SUMMARY

The disclosure provides a semiconductor memory device with reduced process costs and improved electrical reliability by preventing deterioration of a capacitor.

In addition, the features and advantages of the disclosure is not limited to those described above. and other features and advantages could be clearly understood by a person skilled in the art from the description below.

The disclosure provides a semiconductor memory device as described below.

According to an aspect of the disclosure, there is provided a semiconductor memory device including a conductive line elongated in a first horizontal direction, a superlattice layer disposed on the conductive line, a plurality of channel areas arranged to be spaced apart from each other in the first horizontal direction on the superlattice layer and configured to be each connected to the conductive line, a back-gate electrode elongated in a second horizontal direction between a first channel area and a second channel area, which are selected from among the plurality of channel areas and are adjacent to each other, and spaced apart from the conductive line in a vertical direction, the second horizontal direction being perpendicular to the first horizontal direction, and a pair of word lines arranged between the second channel area and a third channel area, which are selected from among the plurality of channel areas and are adjacent to each other, and spaced apart from each other in the first horizontal direction, wherein the superlattice layer includes a first superlattice layer formed by alternately stacking a plurality of first oxide layers and a plurality of first compound layers with each other, and a second superlattice layer formed by alternately stacking a plurality of second oxide layers and a plurality of second compound layers with each other.

According to another aspect of the disclosure, there is provided a semiconductor memory device including a conductive line elongated in a first horizontal direction, a superlattice layer disposed on the conductive line, a plurality of channel areas arranged to be spaced apart from each other in the first horizontal direction at positions spaced apart from the conductive line in a vertical direction, a plurality of contact plugs spaced apart from the conductive line in the vertical direction with the plurality of channel areas therebetween, a back-gate electrode elongated in a second horizontal direction between a first channel area and a second channel area, which are selected from among the plurality of channel areas and are adjacent to each other, and spaced apart from the conductive line in the vertical direction, the second horizontal direction being perpendicular to the first horizontal direction, a back-gate dielectric film arranged between the back-gate electrode and the second channel area and contacting each of the back-gate electrode and the second channel area, a word line spaced apart from the back-gate electrode in the first horizontal direction with the second channel area therebetween, and a gate dielectric film arranged between the word line and the second channel area and contacting each of the word line and the second channel area, wherein the superlattice layer has a structure in which a plurality of oxide layers and a plurality of compound layers are alternately stacked with each other.

According to another aspect of the disclosure, there is provided a semiconductor memory device including a plurality of conductive lines elongated in a first horizontal direction and spaced apart from each other in a second horizontal direction that is perpendicular to the first horizontal direction, a plurality of contact plugs arranged at positions that are spaced apart from the plurality of conductive lines in a vertical direction, a plurality of channel areas arranged between the plurality of conductive lines and the plurality of contact plugs and each including another end that is spaced apart from the plurality of conductive lines in the vertical direction and is connected to one contact plug selected from among the plurality of contact plugs, a plurality of back-gate electrodes elongated in the second horizontal direction between the plurality of conductive lines and the plurality of contact plugs and spaced apart from each other in the first horizontal direction, a plurality of back-gate dielectric films respectively contacting the plurality of back-gate electrodes, a plurality of word lines elongated in the second horizontal direction between the plurality of conductive lines and the plurality of contact plugs, a plurality of gate dielectric films respectively contacting the plurality of word lines, and a superlattice layer arranged between the plurality of channel areas and the plurality of conductive lines, wherein the superlattice layer has a structure in which a plurality of oxide layers and a plurality of compound layers are alternately stacked with each other, and the plurality of compound layers include a material selected from among silicon phosphide (SiP), silicon arsenide (SiAs), and a combination thereof.

### BRIEF DESCRIPTION OF THE DRAWINGS

Implementations of the disclosure will be more clearly understood from the following detailed description taken in conjunction with the accompanying drawings in which:

FIG. 1 is a plan layout diagram illustrating some elements of a semiconductor memory device according to some implementations;

FIG. 2 is a cross-sectional view taken along line X1-X1′ in FIG. 1;

FIGS. 3A and 3B are enlarged cross-sectional views of a region indicated by “EX” in FIG. 2; and

FIGS. 4A to 18B are diagrams for describing, according to a process sequence, a method of manufacturing a semiconductor memory device, according to some implementations, wherein FIGS. 4A, 6A, 7A, 8A, 9A, 10A, 12A, 15A, 16A, and 18A are plan layout diagrams illustrating some elements according to a process sequence to describe a method of manufacturing a semiconductor memory device, and FIGS. 4B, 5, 6B, 7B, 8B, 9B, 10B, 11, 12B, 13, 14, 15B, 16B, 17, and 18B are cross-sectional views of a region corresponding to line X1-X1′ in FIG. 1 according to a process sequence.

### DETAILED DESCRIPTION

Hereinbelow, implementations are described in detail with reference to the accompanying drawings. In the drawings, the same reference characters are used for the same elements, and redundant descriptions of thereof are omitted.

Because the implementations may be modified in various ways, specific implementations are illustrated in the drawings and described in detail in the detailed description. However, this is not intended to limit the scope to specific implementations, and should be understood to include all transformations, equivalents, and substitutes included in the disclosed spirit and technical scope. In describing the implementations, when it is determined that detailed description of related art may obscure the point, the detailed description thereof is omitted.

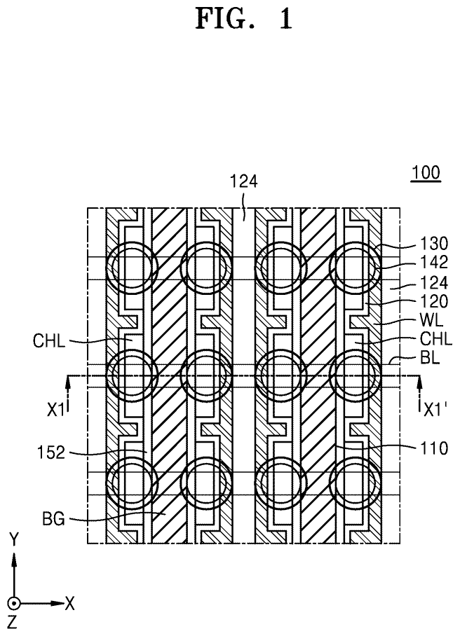

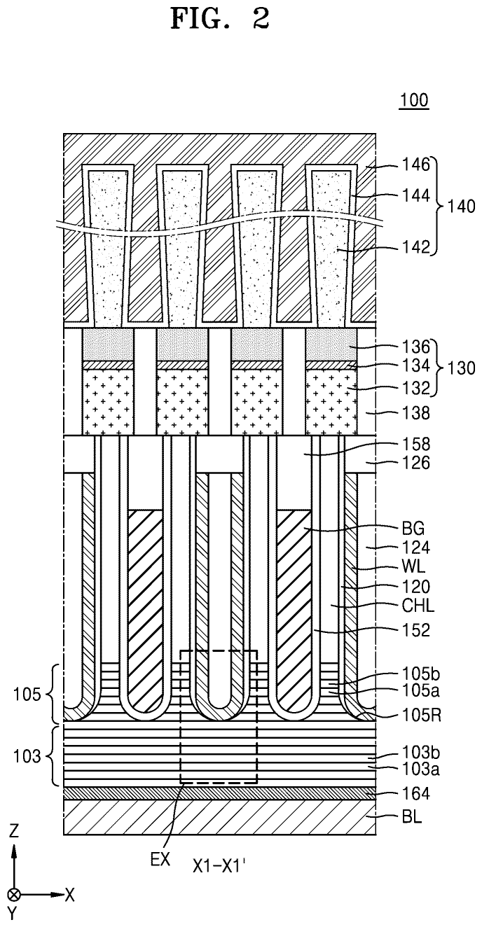

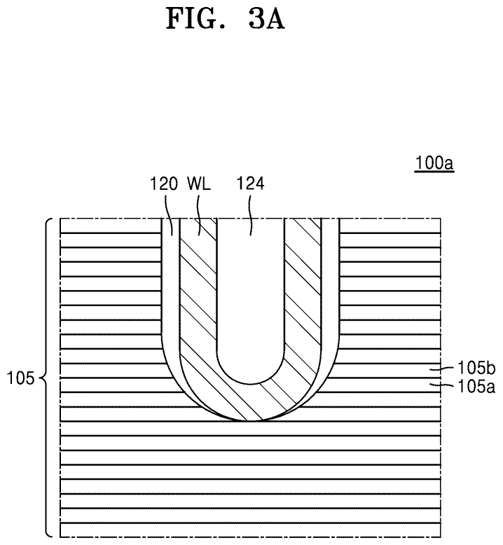

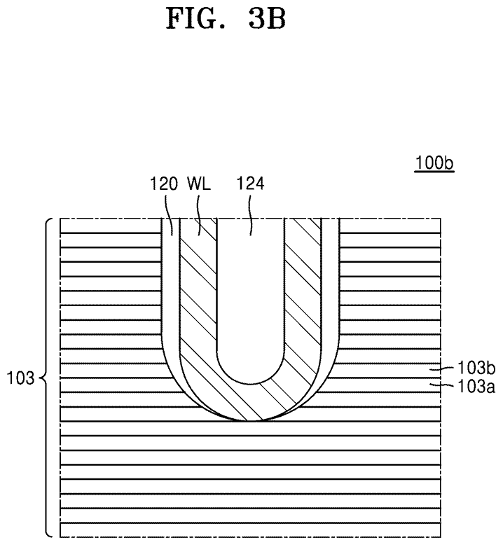

FIG. 1 is a plan layout diagram illustrating some elements of a semiconductor memory device 100 according to some implementations. FIG. 2 is a cross-sectional view taken along line X1-X1′ in FIG. 1, and FIGS. 3A and 3B are enlarged cross-sectional views of a region indicated by “EX” in FIG. 2.

First, referring to FIGS. 1 and 2, the semiconductor memory device 100 includes a plurality of conductive lines BL that are elongated in a first horizontal direction (X direction) and repeatedly arranged to be spaced apart from each other in a second horizontal direction (Y direction), which is perpendicular to the first horizontal direction (X direction). In the semiconductor memory device 100, the plurality of conductive lines BL may each constitute a bit line.

A plurality of channel areas CHL may be disposed on the plurality of conductive lines BL, respectively, and a plurality of contact plugs 130 may be disposed on the plurality of channel areas CHL. The plurality of channel areas CHL may be repeatedly arranged to be spaced apart from each other in the first horizontal direction (X direction) and the second horizontal direction (Y direction), between the plurality of conductive lines BL and the plurality of contact plugs 130. Each of the plurality of channel areas CHL may have one end spaced apart from the plurality of conductive lines BL in a vertical direction (Z direction) and the other end connected to one contact plug 130 selected from among the plurality of contact plugs 130. The plurality of channel areas CHL may be physically spaced apart from the conductive lines BL, respectively, and may each be in contact with the one contact plug 130.

Each of the plurality of conductive lines BL may contain polysilicon doped with metal or conductive metal nitride. For example, each of the plurality of conductive lines BL may contain titanium (Ti), titanium nitride (TiN), tantalum (Ta), tantalum nitride (TaN), molybdenum (Mo), ruthenium (Ru), tungsten (W), tungsten nitride (WN), cobalt (Co), nickel (Ni), ruthenium titanium nitride (RuTiN), or any combinations thereof.

The plurality of contact plugs 130 may be spaced apart from the plurality of conductive lines BL in the vertical direction (Z direction) with the plurality of channel areas CHL therebetween. The plurality of contact plugs 130 may be arranged in a matrix arrangement to be spaced apart from each other in the first horizontal direction (X direction) and in the second horizontal direction (Y direction). The plurality of contact plugs 130 may be connected to the plurality of channel areas CHL, respectively.

Each of the plurality of contact plugs 130 may contain metal, conductive metal nitride, metal silicide, doped polysilicon, or any combinations thereof. For example, each of the plurality of contact plugs 130 may contain Ti, TiN, Ta, TaN, Mo, Ru, W, WN, Co, NI, titanium silicide (TiSi), titanium silicon nitride (TiSiN), tungsten silicide (WSi), tungsten silicon nitride (WSiN), tantalum silicide (TaSi), tantalum silicon nitride (TaSiN), ruthenium titanium nitride (RuTiN), cobalt silicide (CoSi), nickel silicide (NiSi), doped polysilicon, or any combinations thereof. In some implementations, each of the plurality of contact plugs 130 includes, as shown in FIG. 2, a first conductive pattern 132, a second conductive pattern 134, and a third conductive pattern 136 that are sequentially stacked on the plurality of channel areas CHL. For example, the first conductive pattern 132 may contain doped polysilicon, the second conductive pattern 134 may contain metal silicide, and the third conductive pattern 136 may contain metal, but the disclosure is not limited thereto.

As shown in FIG. 1, the plurality of channel areas CHL may include a first group of channel areas CHL that are arranged in a row in the first horizontal direction (X direction) and spaced apart from each other in the first horizontal direction (X direction), and a second group of channel areas CHL that are arranged in a row in the second horizontal direction (Y direction) and spaced apart from each other in the second horizontal direction (Y direction). Each of the plurality of contact plugs 130 may be disposed on one channel area CHL selected from among the plurality of channel areas CHL. Each of the plurality of contact plugs 130 may pass through an interlayer insulating film 138 and may be in contact with the selected one channel area CHL. The interlayer insulating film 138 may contain a silicon oxide film, a silicon nitride film, or a combination thereof.

Herein, terms such as “first”, “second”, and “third” are used to describe various elements, but those terms are not intended to limit the elements. These terms are merely used to distinguish one element from another element, and unless specifically stated to the contrary, a first element may be a second element or a third element. For example, without departing from the scope of various implementations described below, a first channel area may be referred to as a second channel area or a third channel area, and similarly, the second channel area or the third channel area may be referred to as the first channel area. Each of the first channel area, the second channel area, and the third channel area is a channel area, but the first channel area, the second channel area, and the third channel area are not necessarily be the same channel area.

In some implementations, each of the plurality of channel areas CHL may contain silicon such as monocrystalline silicon, polycrystalline silicon, or amorphous silicon. In other implementations, each of the plurality of channel areas CHL may contain at least one of germanium (Ge), silicon-germanium (SiGe), silicon carbide (SiC), gallium arsenide (GaAs), indium arsenide (InAs), and indium phosphide (InP). In some implementations, the channel area CHL may contain a conductive area, a well doped with impurities, or a structure doped with impurities.

A plurality of back-gate electrodes BG and a plurality of word lines WL may be disposed on each of the plurality of conductive lines BL. Each of the plurality of back-gate electrodes BG and the plurality of word lines WL may be elongated in the second horizontal direction (Y direction) between the plurality of conductive lines BL and the plurality of contact plugs 130. Each of the plurality of back-gate electrodes BG and the plurality of word lines WL may be spaced apart from each other in the first horizontal direction (X direction).

In the plurality of back-gate electrodes BG and the plurality of word lines WL that are arranged in a row in the first horizontal direction (X direction) on one conductive line BL, one back-gate electrode BG and a pair of word lines WL may be alternately arranged with each other, and the one back-gate electrode BG and the pair of word lines WL may be spaced apart from each other with one channel area CHL therebetween. In other words, the plurality of word lines WL may be arranged so that a pair of word lines WL adjacent to each other are arranged between each of the plurality of back-gate electrodes BG.

Each of the plurality of back-gate electrodes BG may contain metal, conductive metal nitride, doped polysilicon, or any combinations thereof. For example, each of the plurality of back-gate electrodes BG may contain Ti, TiN, Ta, TaN, Mo, Ru, W, WN, TiSiN, WSiN, doped polysilicon, or any combinations thereof, but is not limited thereto. Each of the plurality of word lines WL may contain metal, conductive metal nitride, or any combinations thereof. For example, each of the plurality of word lines WL may contain Ti, TiN, Ta, TaN, Mo, Ru, W, WN, TiSiN, WSiN, or any combinations thereof, but is not limited thereto.

Each of the plurality of back-gate electrodes BG may be elongated in the second horizontal direction (Y direction) between two channel areas CHL adjacent to each other in the first horizontal direction (X direction). Each of the plurality of back-gate electrodes BG may be arranged at a position spaced apart in the vertical direction (Z direction) from each of the conductive line BL and the plurality of contact plugs 130.

The semiconductor memory device 100 includes a plurality of back-gate dielectric films 152 covering the plurality of back-gate electrodes BG. Each of the plurality of back-gate dielectric films 152 may be located between one back-gate electrode BG and one channel area CHL. Each of the plurality of back-gate dielectric films 152 may be in contact with an adjacent back-gate electrode BG and an adjacent channel area CHL.

Between a pair of channel areas CHL adjacent to each other, a first capping insulating pattern 158 may be arranged between the back-gate electrode BG and the plurality of contact plugs 130. The first capping insulating pattern 158 and the back-gate electrode BG may be arranged to overlap each other in the vertical direction (Z direction). The first capping insulating pattern 158 may contain a silicon oxide film, a silicon nitride film, or a combination thereof.

Each of the plurality of word lines WL may be arranged at a position spaced apart in the vertical direction (Z direction) from each of the conductive line BL and the plurality of contact plugs 130. A pair of word lines WL may be arranged between each of the plurality of back-gate electrodes BG in the first horizontal direction (X direction). The pair of word lines WL may be spaced apart in the first horizontal direction (X direction) from an adjacent back-gate electrode BG with one channel area CHL therebetween.

As shown in FIG. 2, a first superlattice layer 103 and a second superlattice layer 105 may be located between the plurality of channel areas CHL and the conductive line BL. The first superlattice layer 103 and the second superlattice layer 105 may serve as a direct contact plug DC. The first superlattice layer 103 and the second superlattice layer 105 may also serve as an etch stop film during a manufacturing process for the second superlattice layer 105 later.

The first superlattice layer 103 includes a first oxide layer 103a and a first compound layer 103b. In some implementations, the first oxide layer 103a may contain silicon oxide. In some implementations, the first oxide layer 103a may contain silicon dioxide (SiO₂). In some implementations, a concentration of oxygen atoms in the first oxide layer 103a may be in a range of 10¹⁷/cm³ to 10²²/cm³. In some implementations, the first compound layer 103b may contain silicon phosphide (SiP). In some implementations, a concentration of phosphorus in the first compound layer 103b may be in a range of 10¹⁶/cm³ to 10²²/cm³. In some implementations, the number of superlattices in the first oxide layer 103a formed by the first oxide layer 103a and the first compound layer 103b may be in a range of 1 to 100.

The second superlattice layer 105 includes a second oxide layer 105a and a second compound layer 105b. In some implementations, the second oxide layer 105a may contain silicon oxide. In some implementations, the second oxide layer 105a may contain SiO₂. In some implementations, a concentration of oxygen atoms in the second oxide layer 105a may be in a range of 10¹⁷/cm³ to 10²²/cm³. In some implementations, the second compound layer 105b may contain silicon arsenide (SiAs). In some implementations, a concentration of arsenic in the second compound layer 105b may be in a range of 10¹⁶/cm³ to 10²²/cm³. In some implementations, the number of superlattices in the second superlattice layer 105 formed by the second oxide layer 105a and the second compound layer 105b may be in a range of 1 to 100.

In some implementations, the sum of thicknesses of the first superlattice layer 103 and the second superlattice layer 105 may correspond to a range of 1 nm to 100 nm. In FIG. 2, each of the first compound layer 103b and the second compound layer 105b contains phosphorous (P) and arsenic (As). However, the disclosure is not limited thereto, and a compound layer may contain other P-type dopants such as antimony (Sb).

A separation insulating pattern 124 may be arranged between a pair of word lines WL that are arranged between a pair of channel areas CHL adjacent to each other. A first buried insulating pattern 126 may be arranged between the pair of word lines WL and the plurality of contact plugs 130. The word line WL and the first buried insulating pattern 126 may be arranged to overlap each other in the vertical direction (Z direction) between a pair of channel areas CHL adjacent to each other. The pair of word lines WL may be spaced apart in the vertical direction (Z direction) from the plurality of contact plugs 130 with the first buried insulating pattern 126 therebetween.

Each of the separation insulating pattern 124 and the first buried insulating pattern 126 may contain a silicon oxide film, a silicon nitride film, or any combinations thereof. In some implementations, the separation insulating pattern 124 and the first buried insulating pattern 126 may contain identical or similar materials to each other. In other implementations, the separation insulating pattern 124 and the first buried insulating pattern 126 may contain different materials from each other.

A gate dielectric film 120 may be located between each of the plurality of word lines WL and a channel area CHL adjacent thereto. A pair of gate dielectric films 120 may be arranged between a pair of channel areas CHL adjacent to each other, and a pair of word lines WL may be arranged between the pair of gate dielectric films 120. Each of the pair of gate dielectric films 120 may include one end that is in contact with the conductive line BL and the other end that is in contact with one contact plug 130 selected from among the plurality of contact plugs 130.

A metal silicide film 164 may be located between the first and second superlattice layers 103 and 105 and the conductive line BL. The metal silicide film 164 may contain TiSi, WSi, TaSi, CoSi, NiSi, or any combinations thereof, but is not limited thereto.

In some implementations, each of the gate dielectric film 120 and the back-gate dielectric film 152 may contain a silicon oxide film, a high-dielectric film, or any combinations thereof. The high-dielectric film may refer to a film having a dielectric constant than a silicon oxide film. In some implementations, each of the gate dielectric film 120 and the back-gate dielectric film 152 may contain at least one material selected from among silicon oxide, hafnium oxide (HfO), hafnium silicate (HfSiO), hafnium oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium bismuth (SrTiO), yttrium oxide (YO), aluminum oxide (AlO), and lead scandium tantalum oxide (PbScTaO). The plurality of back-gate electrodes BG, the plurality of word lines WL, the plurality of channel areas CHL, the plurality of back-gate dielectric films 152, and the plurality of gate dielectric films 120 arranged between the plurality of conductive lines BL and the plurality of contact plugs 130 may constitute a plurality of vertical channel transistors.

As shown in FIGS. 1 and 2, a capacitor structure 140 may be disposed on the plurality of contact plugs 130 and the interlayer insulating film 138. The capacitor structure 140 includes a plurality of lower electrodes 142, a capacitor dielectric film 144 that conformally covers a surface of each of the plurality of lower electrodes 142, and an upper electrode 146 that covers the plurality of lower electrodes 142 with the capacitor dielectric film 144 therebetween. Each of the plurality of lower electrodes 142 may be connected to the channel area CHL through one contact plug 130 selected from among the plurality of contact plugs 130. The third conductive pattern 136 included in each of the plurality of contact plugs 130 may function as a landing pad with which one lower electrode 142 selected from among the plurality of lower electrodes 142 is in contact.

FIGS. 3A and 3B are enlarged cross-sectional views of a region indicated by “EX” in FIG. 2. A semiconductor memory device 100a in FIG. 3A and a semiconductor memory device 100b in FIG. 3B only differ from the semiconductor memory device 100 in FIG. 2 with respect to the first and second superlattice layers 103 and 105 part (see FIG. 2), and the remaining elements are the same. Thus, illustration and description of the same element are omitted, and differences are mainly described below.

Unlike the semiconductor memory device 100 in FIG. 2 in which the second superlattice layer 105 is disposed on the first superlattice layer 103, the semiconductor memory device 100a in FIG. 3A includes only the second superlattice layer 105. The second superlattice layer 105 may include a structure in which the second oxide layer 105a and the second compound layer 105b are alternately stacked with each other. In some implementations, the second oxide layer 105a may contain silicon oxide. In some implementations, a concentration of oxygen atoms in the second oxide layer 105a may be in a range of 10¹⁷/cm³ to 10²²/cm³. In some implementations, the second compound layer 105b may contain SiAs. In some implementations, a concentration of arsenic in the second compound layer 105b may be in a range of 10¹⁶/cm³ to 10²²/cm³. In some implementations, the number of superlattices in the second superlattice layer 105 formed by the second oxide layer 105a and the second compound layer 105b may be in a range of 1 to 100.

The semiconductor memory device 100b in FIG. 3B includes only the first superlattice layer 103. The first superlattice layer 103 may include a structure in which the first oxide layer 103a and the first compound layer 103b are alternately stacked on each other. In some implementations, the first oxide layer 103a may contain silicon oxide. In some implementations, a concentration of oxygen atoms in the first oxide layer 103a may be in a range of 10¹⁷/cm³ to 10²²/cm³. In some implementations, the first compound layer 103b may contain SiP. In some implementations, a concentration of phosphorus in the first compound layer 103b may be in a range of 10¹⁶/cm³ to 10²²/cm³. In some implementations, the number of superlattices in the first oxide layer 103a formed by the first oxide layer 103a and the first compound layer 103b may be in a range of 1 to 100.

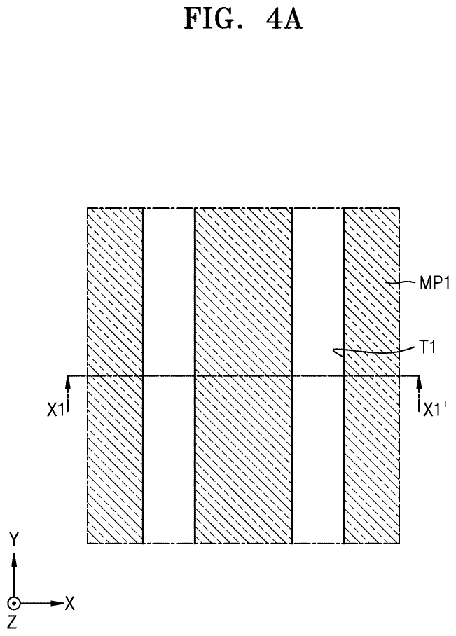

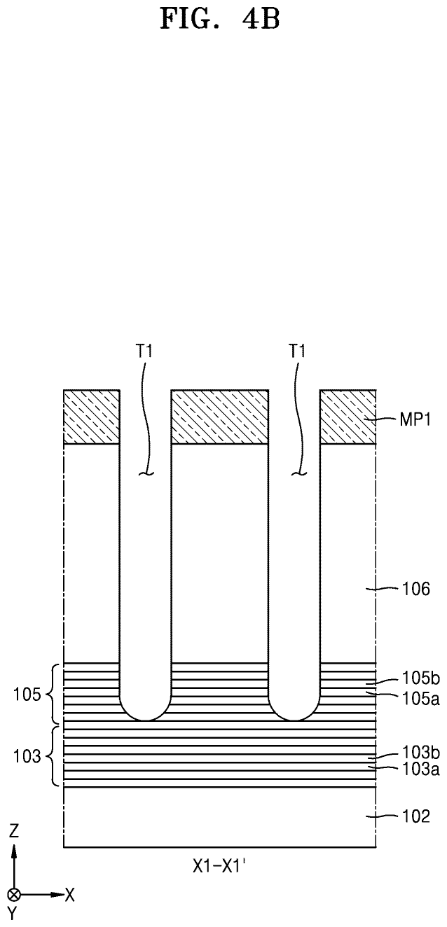

FIGS. 4A to 18B are diagrams for describing, according to a process sequence, a method of manufacturing a semiconductor memory device, according to some implementations. More specifically, FIGS. 4A, 6A, 7A, 8A, 9A, 10A, 12A, 15A, 16A, and 18A are plan layout diagrams illustrating some elements according to a process sequence to describe a method of manufacturing a semiconductor memory device. FIGS. 4B, 5, 6B, 7B, 8B, 9B, 10B, 11, 12B, 13, 14, 15B, 16B, 17, and 18B are cross-sectional views of a region corresponding to line X1-X1′ in FIG. 1 according to a process sequence. An example of a method of manufacturing the semiconductor memory device 100 shown in FIGS. 1 and 2 is described with reference to FIGS. 4A to 18B. In FIGS. 4A to 18B, the same reference characters as those of FIGS. 1 and 2 denote the same member, and redundant descriptions thereof are omitted herein.

Referring to FIGS. 4A and 4B, a substrate structure including a substrate 102, the first superlattice layer 103, the second superlattice layer 105, and an active layer 106 may be prepared.

The substrate 102 may be a silicon substrate. The first superlattice layer 103 may have a structure in which the first oxide layer 103a and the first compound layer 103b are sequentially stacked. The second superlattice layer 105 may have a structure in which the second oxide layer 105a and the second compound layer 105b are sequentially stacked. The active layer 106 may include at least one selected from among Ge, SiGe, SiC, GaAs, InAs, and InP. In some implementations, the active layer 106 may include a well doped with impurities or a structure doped with impurities.

A mask pattern MP1 may be formed on the active layer 106 of the substrate structure. The mask pattern MP1 may contain a silicon nitride film. In some implementations, an oxide film may be located between the active layer 106 and the mask pattern MP1.

The mask pattern MP1 may be used as an etch mask to etch some areas of the substrate structure and form a plurality of first trenches T1. The plurality of first trenches T1 may be formed to pass through the active layer 106 and a portion of the first and second oxide layers 103 and 105 in the vertical direction (Z direction) and to be elongated in the second horizontal direction (Y direction).

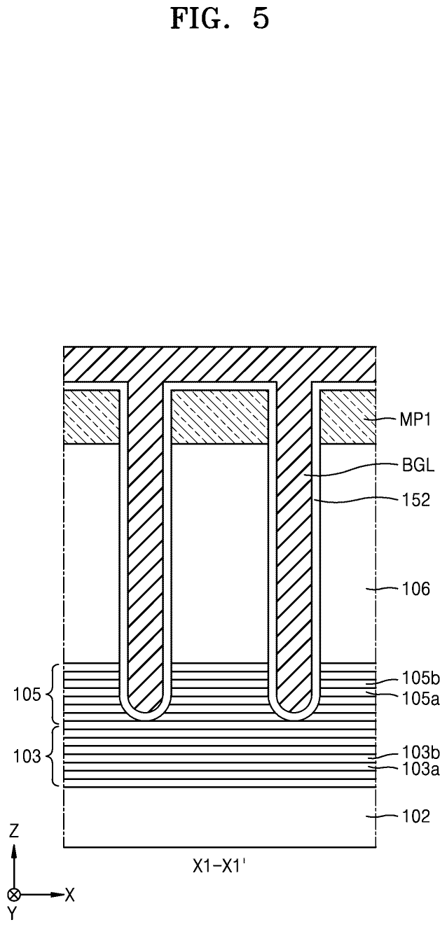

Referring to FIG. 5, in the product of FIGS. 4A and 4B, the back-gate dielectric film 152 conformally covering inner walls of the plurality of first trenches T1 and a surface of each of the mask patterns MP1 and a back-gate conductive layer BGL filling the plurality of first trenches T1 on the back-gate dielectric film 152 may be formed. A material of the back-gate conductive layer BGL is substantially the same as that described above for a material of the back-gate electrode BG.

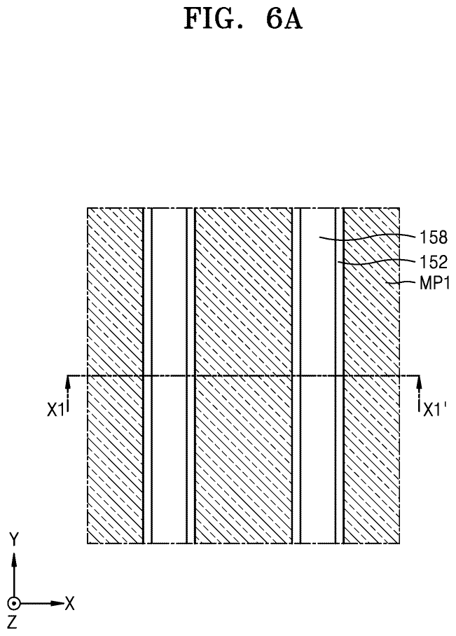

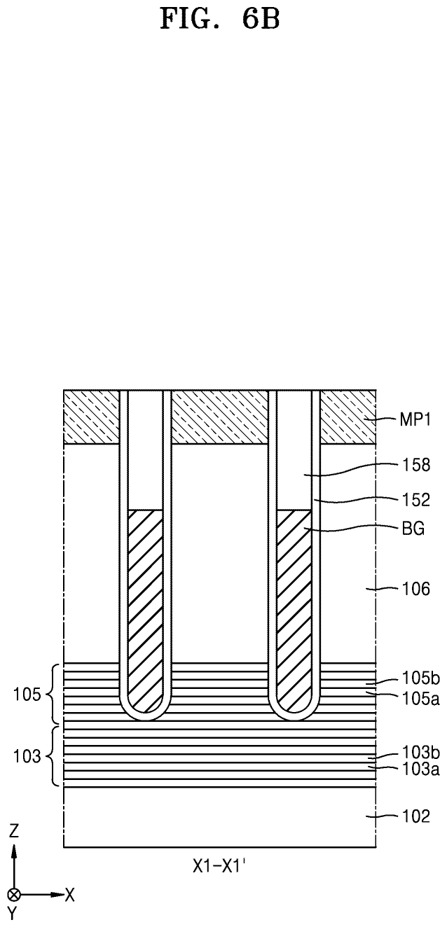

Referring to FIGS. 6A and 6B, in the product of FIG. 5, the back-gate conductive layer BGL may be etch-backed to form the plurality of back-gate electrodes BG in the plurality of first trenches T1, an upper space of each of the plurality of first trenches T1 may be filled with the first capping insulating pattern 158, and a product thus obtained may be flattened to expose an upper surface of the mask pattern MP1.

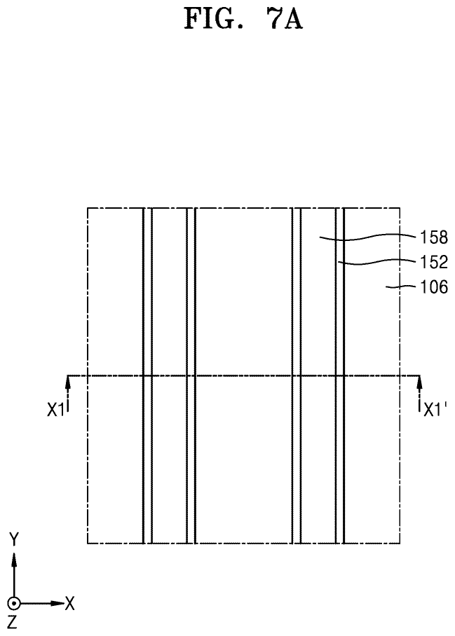

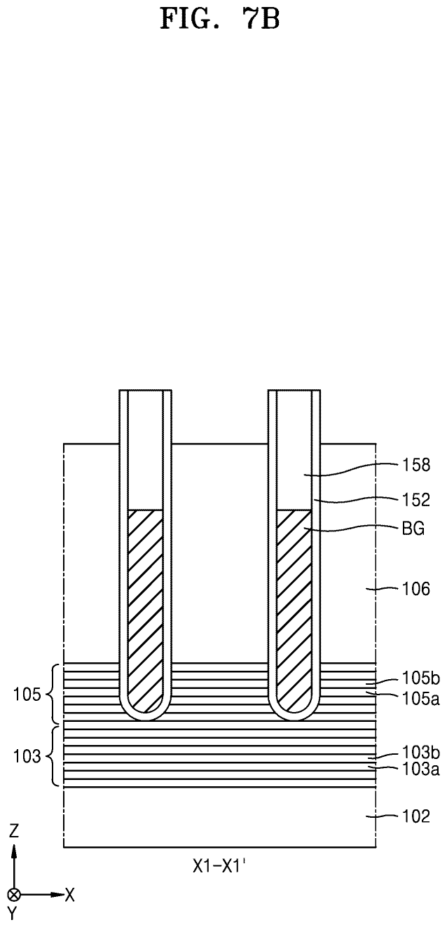

Referring to FIGS. 7A and 7B, the mask pattern MP1 may be removed from the product of FIGS. 6A and 6B to expose the active layer 106 around the plurality of first capping insulating patterns 158 and the plurality of back-gate dielectric films 152.

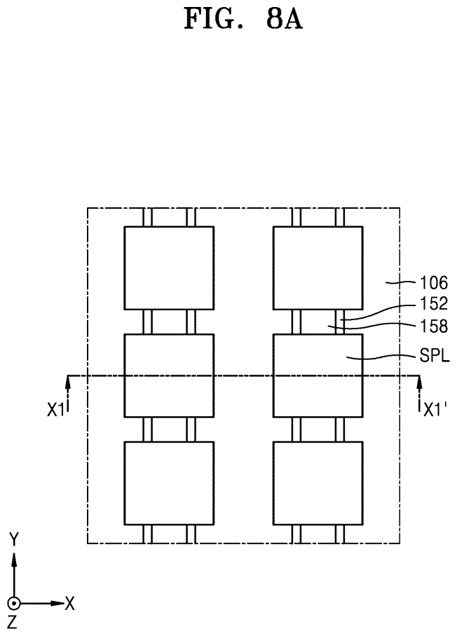

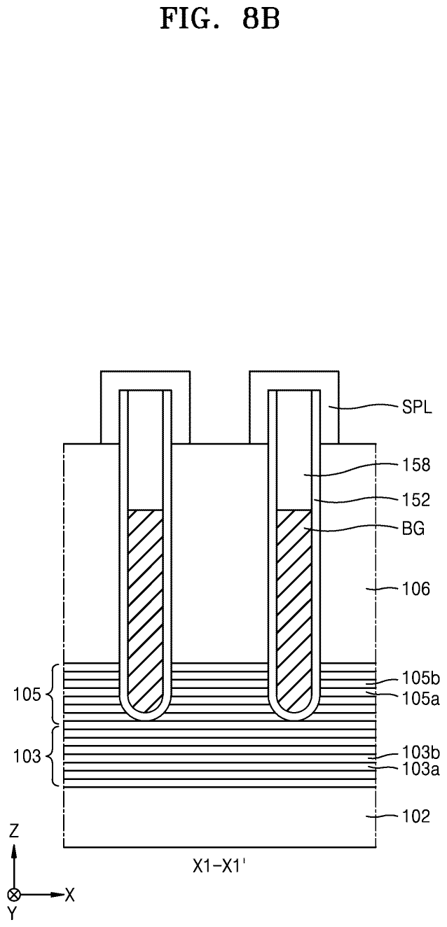

Referring to FIGS. 8A and 8B, a plurality of spacer layers SPL may be formed to cover a partial area of each of the plurality of first capping insulating patterns 158 and the plurality of back-gate dielectric films 152 and a partial area of the active layer 106 present therearound. Each of the plurality of spacer layers SPL may contain a silicon oxide film. The plurality of spacer layers SPL may include a first group of spacer layers SPL that are arranged in a row in the first horizontal direction (X direction) and spaced apart from each other in the first horizontal direction (X direction), and a second group of spacer layers SPL that are arranged in a row in the second horizontal direction (Y direction) and spaced apart from each other in the second horizontal direction (Y direction).

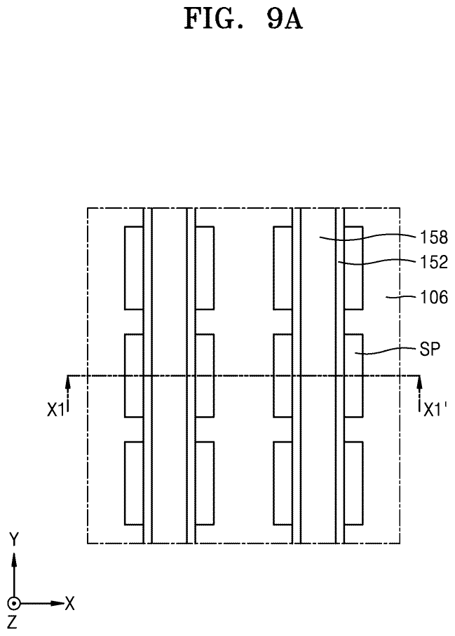

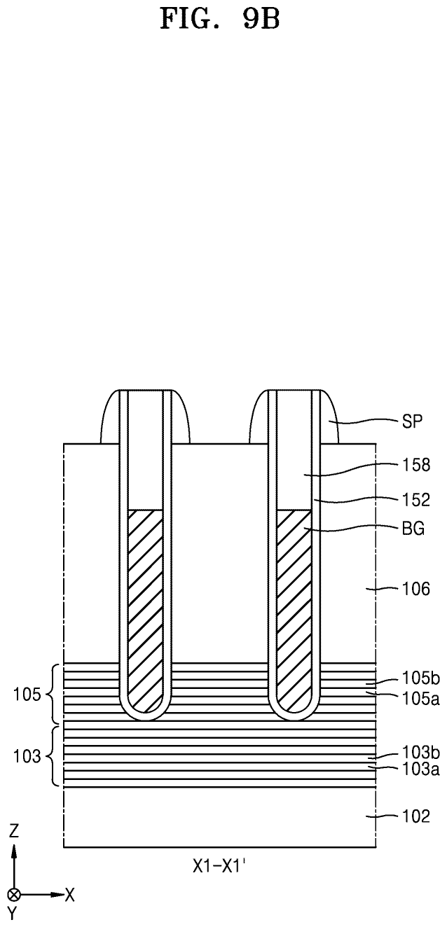

Referring to FIGS. 9A and 9B, the plurality of spacer layers SPL may be etch-backed to form a plurality of spacers SP that cover opposite side walls of each of a plurality of structures in the first horizontal direction (X direction), the plurality of structures including the first capping insulating pattern 158 and the back-gate dielectric film 152. Some areas of an upper surface of the active layer 106 adjacent to the structure may be covered by the plurality of spacers SP.

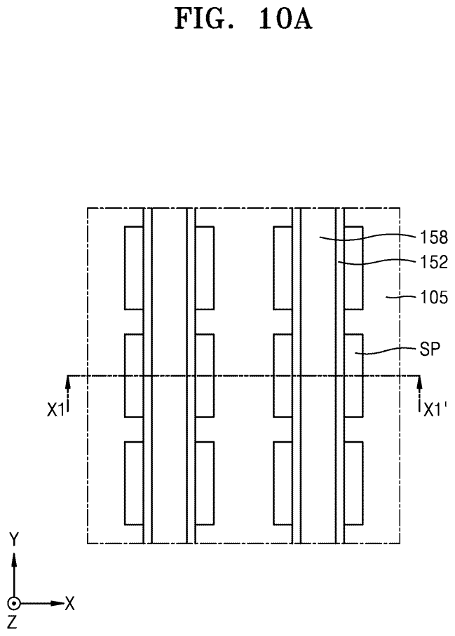

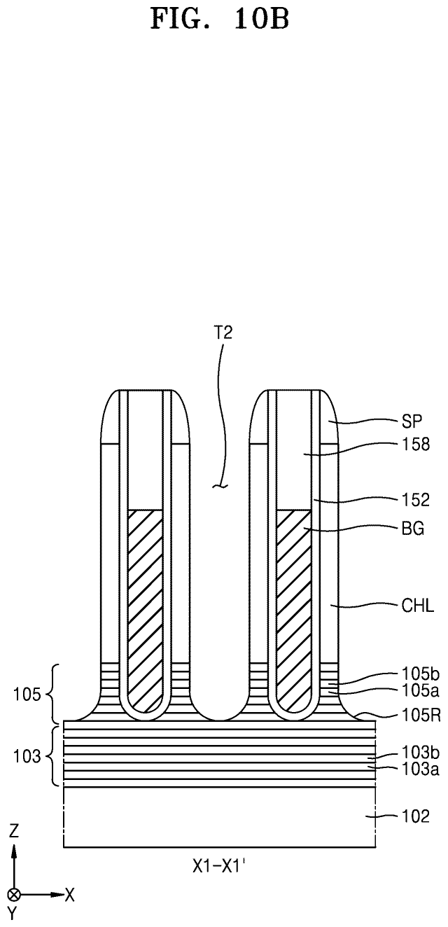

Referring to FIGS. 10A and 10B, the active layer 106 may be etched by using the plurality of first capping insulating patterns 158, the plurality of back-gate dielectric films 152, and the plurality of spacers SP as an etch mask to form a plurality of second trenches T2. As a result, portions of the active layer 106 present under the plurality of spacers SP may remain as the plurality of channel areas CHL. During the process of etching the active layer 106, a portion of a buried insulating layer 104 may be etched due to excessive etching so that a plurality of recess areas 105R connected to the plurality of second trenches T2 may be formed on an upper surface of the second superlattice layer 105.

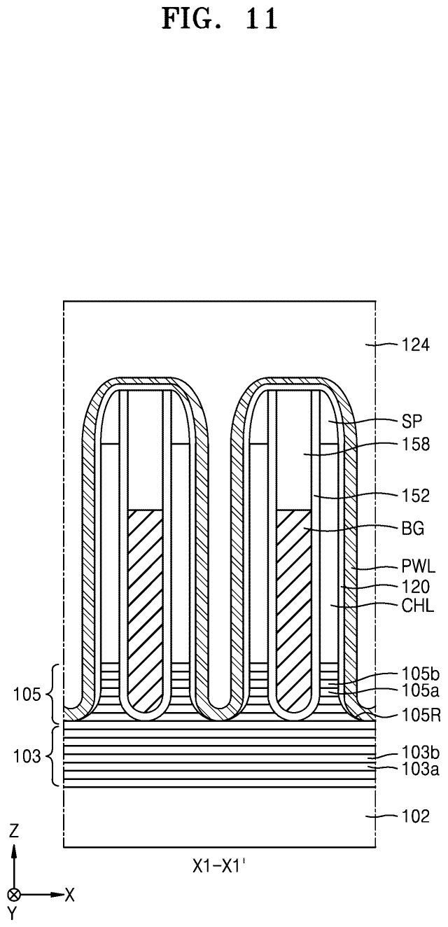

Referring to FIG. 11, after the gate dielectric film 120 conformally covering the product of FIGS. 10A and 10B is formed and a conductive layer conformally covering the gate dielectric film 120 is formed, a portion of the conductive layer may be etched in the recess area 105R of the buried insulating layer 104 to separate the conductive layer into a plurality of preliminary word lines PWL. Thereafter, the separation insulating pattern 124 filling in upper spaces of the plurality of preliminary word lines PWL may be formed. The separation insulating pattern 124 may be formed to fill in a space between each of the plurality of preliminary word lines PWL and cover an upper surface of each of the plurality of preliminary word lines PWL. A material of the conductive layer is as described above for a material of the word line WL.

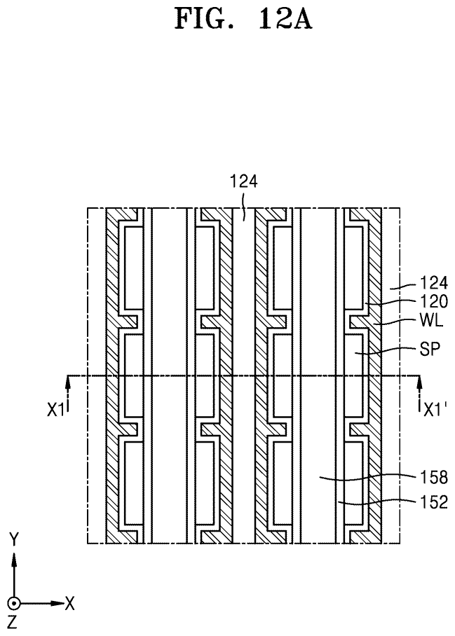

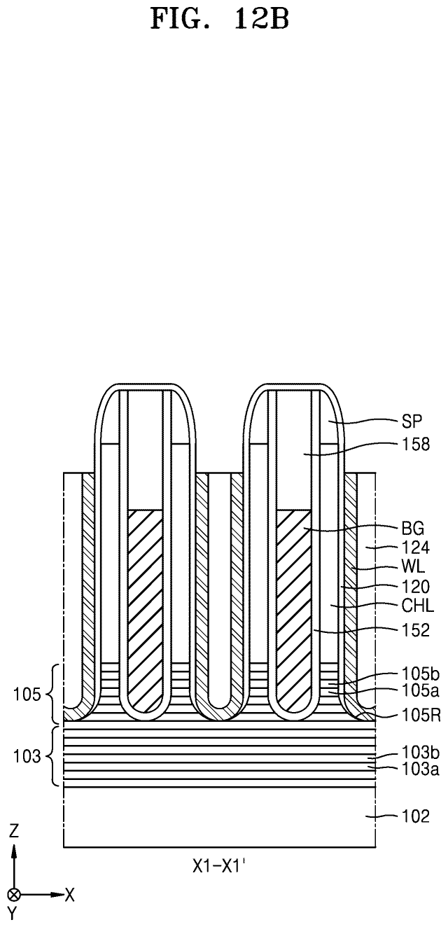

Referring to FIGS. 12A and 12B, in the product of FIG. 11, the separation insulating pattern 124 may be etch-backed to remove a portion of an upper layer of the separation insulating pattern 124 so that a portion of each of the plurality of preliminary word lines PWL is exposed, and each of the plurality of exposed preliminary word lines PWL may be etched to form the plurality of word lines WL.

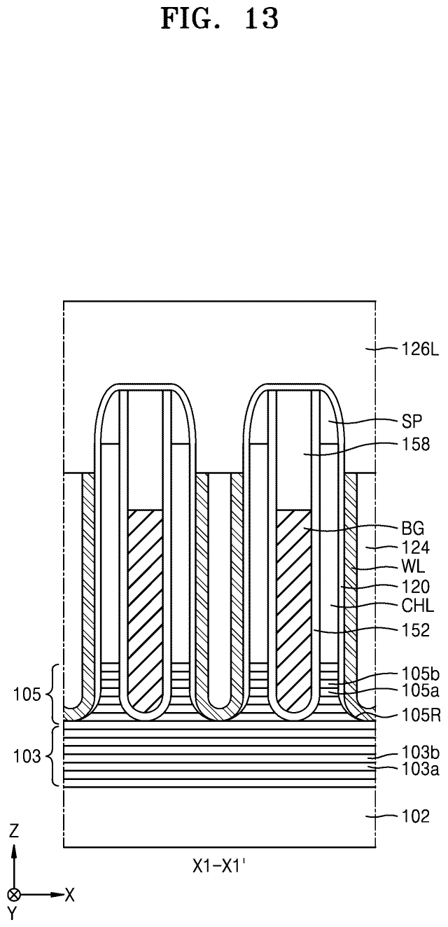

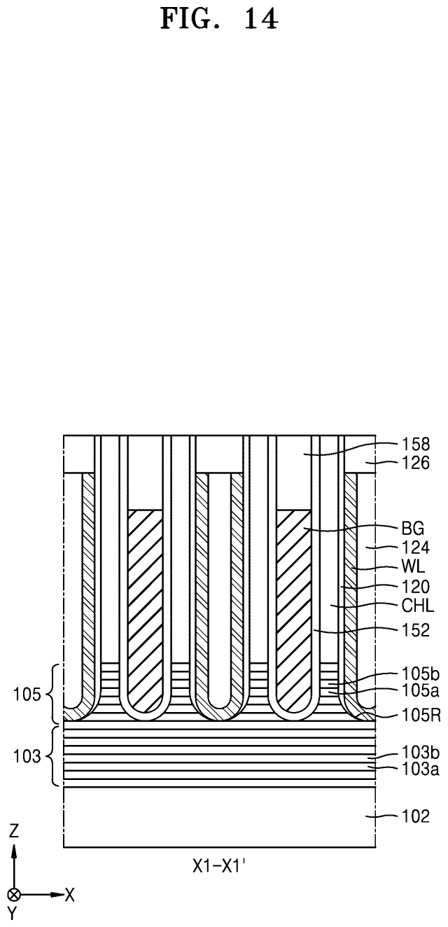

Referring to FIG. 13, a first buried insulating film 126L covering the product of FIGS. 12A and 12B may be formed. The material of the first buried insulating film 126L can be the same as the material of the first buried insulating pattern 126 as described above.

Referring to FIG. 14, in the product of FIG. 13, a planarization process may be performed on the exposed upper surface of the first buried insulating film 126L to expose the plurality of channel areas CHL, and the first buried insulating pattern 126 may be formed from the first buried insulating film 126L. After the plurality of channel areas CHL are exposed, a height of an uppermost portion of each of the first capping insulating pattern 158 and the gate dielectric film 120 in the product of FIG. 13 may be lowered.

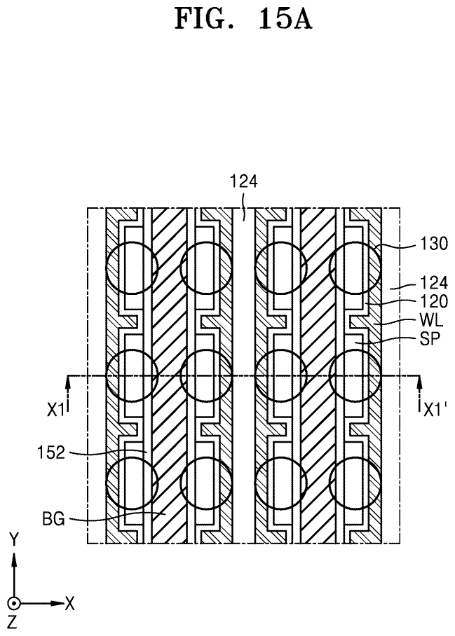

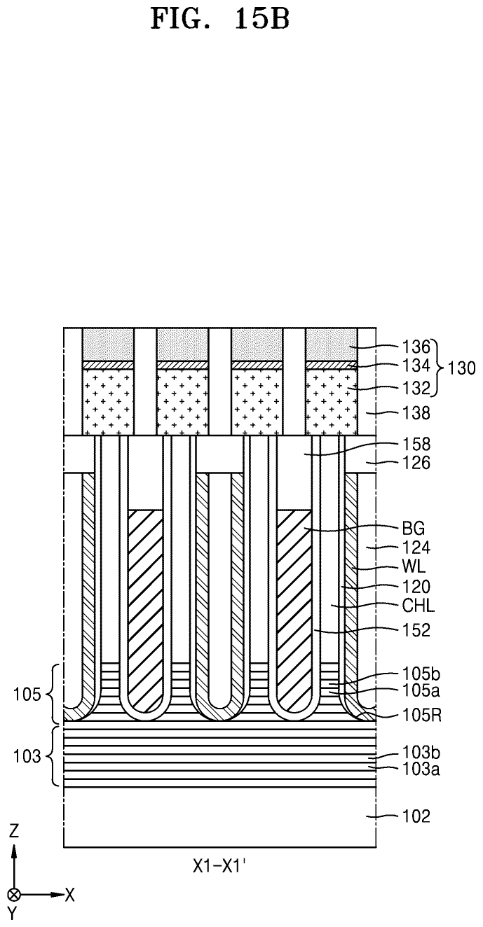

Referring to FIGS. 15A and 15B, in the product of FIG. 14, the plurality of contact plugs 130 may be formed on the plurality of channel areas CHL, and the interlayer insulating film 138 filling in a space between each of the plurality of contact plugs 130 may be formed.

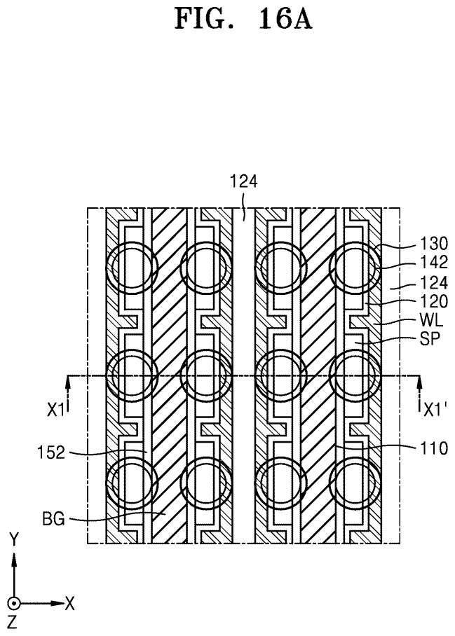

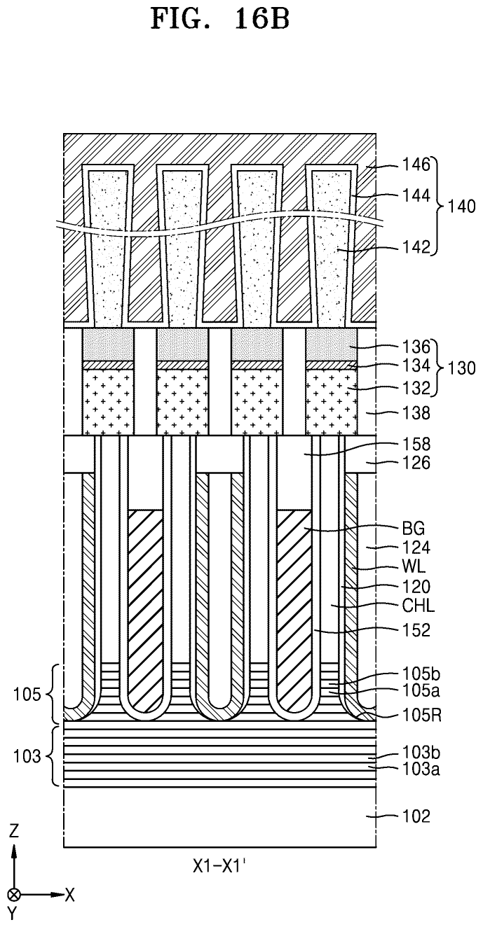

Referring to FIGS. 16A and 16B, the capacitor structure 140 connected to the plurality of contact plugs 130 may be formed on the product of FIGS. 15A and 15B.

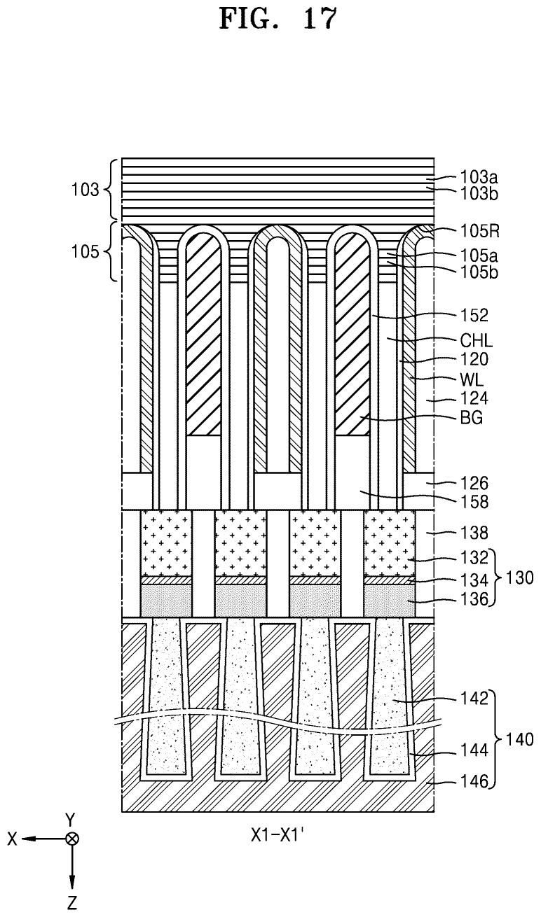

Referring to FIG. 17, the substrate 102 may face upward in the vertical direction (Z direction) by turning over the product of FIGS. 16A and 16B upside down in the vertical direction (Z direction), and a grinding process and a wet etching process may be sequentially performed on the substrate 102 from an exposed backside surface of the substrate 102 until the first superlattice layer 103 is exposed. The first and second superlattice layers 103 and 105 may function as the direct contact plug DC later. By forming the first and second superlattice layers 103 and 105, which function as the direct contact plug DC, before the capacitor structure 140, a process may be performed in a range of 430° C. or lower, unlike when the direct contact plug DC is formed after the capacitor structure 140 is formed, and thus, there is less concern that the semiconductor memory device including other elements will be damaged by heat.

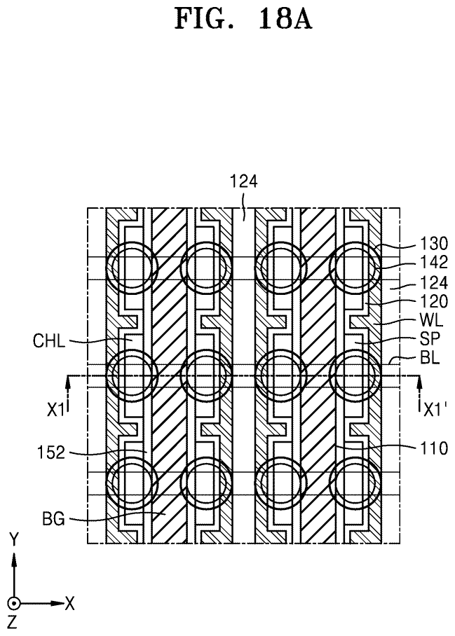

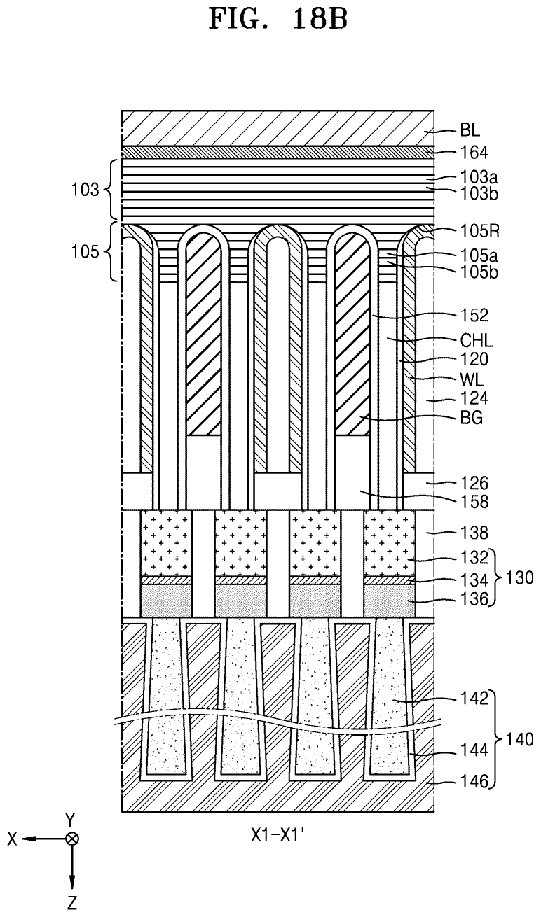

Referring to FIGS. 18A and 18B, in the product of FIG. 17, the metal silicide film 164 and the conductive line BL covering an exposed surface of the first superlattice layer 103 may be formed, so that the semiconductor memory device 100 shown in FIGS. 1 and 2 may be manufactured.

The semiconductor memory device 100a shown in FIG. 3A may be obtained by performing the processes of FIGS. 5A to 18B after forming the second superlattice layer 105, the second superlattice layer 105 being obtained by alternately stacking only the second oxide layer 105a and the second compound layer 105b without the first superlattice layer 103 on the substrate 102 in the process of FIGS. 4A and 4B. The semiconductor memory device 100b shown in FIG. 3B may be obtained by performing the processes of FIGS. 5A to 18B after forming the first superlattice layer 103, the first superlattice layer 103 being obtained by alternately stacking only the first oxide layer 103a and the first compound layer 103b without the second superlattice layer 105 on the substrate 102 in the process of FIGS. 4A and 4B.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the disclosure has been particularly shown and described with reference to implementations thereof, it will be understood that various changes in form and details may be made therein without departing from the spirit and scope of the following claims.

What is claimed is:

1. A semiconductor memory device comprising:
a conductive line extending in a first direction;
a superlattice layer disposed on the conductive line;
a plurality of channel areas spaced apart from each other in the first direction on the superlattice layer and each connected to the conductive line;
a back-gate electrode extending in a second direction between a first channel area and a second channel area of the plurality of channel areas, the first channel area and the second channel area being adjacent to each other, wherein the back-gate electrode is spaced apart from the conductive line in a third direction, and wherein the second direction is perpendicular to the first direction; and
a pair of word lines arranged between the second channel area and a third channel area of the plurality of channel areas, the second channel area and the third channel area being adjacent to each other, wherein the pair of word lines are spaced apart from each other in the first direction,
wherein the superlattice layer comprises a first superlattice layer comprising a plurality of first oxide layers and a plurality of first compound layers that are alternately stacked on each other, and wherein the superlattice layer comprises a second superlattice layer comprising a plurality of second oxide layers and a plurality of second compound layers that are alternately stacked on each other.

2. The semiconductor memory device of claim 1, wherein the second superlattice layer is arranged on the first superlattice layer.

3. The semiconductor memory device of claim 1, wherein the first compound layer comprises silicon phosphide (SiP), and the second compound layer comprises silicon arsenide (SiAs).

4. The semiconductor memory device of claim 1, wherein a thickness of the superlattice layer in the third direction is in a range of about 1 nm to about 100 nm.

5. The semiconductor memory device of claim 1, wherein a concentration of oxygen (O) atoms included in the first oxide layer and the second oxide layer is in a range of about 10¹⁷/cm³ to about 10²²/cm³.

6. The semiconductor memory device of claim 1, wherein a concentration of phosphorus (P) included in the first compound layer is in a range of about 10¹⁶/cm³ to about 10²²/cm³.

7. The semiconductor memory device of claim 1, wherein a concentration of arsenic (As) included in the second compound layer is in a range of about 10¹⁶/cm³ to about 10²²/cm³.

8. The semiconductor memory device of claim 1, wherein the first oxide layer and the second oxide layer comprise a same material.

9. The semiconductor memory device of claim 1, further comprising a metal silicide film between the superlattice layer and the conductive line.

10. The semiconductor memory device of claim 1, further comprising a plurality of contact plugs spaced apart from the conductive line in the third direction, wherein the plurality of channel areas are respectively arranged between the plurality of contact plugs and the conductive line, and wherein each contact plug of the plurality of contact plugs is in contact with a channel area of the plurality of channel areas, and
wherein the back-gate electrode has a first end surface that faces the plurality of contact plugs and a second end surface that faces the superlattice layer and the conductive line.

11. The semiconductor memory device of claim 1, further comprising:
a back-gate dielectric film located between the second channel area and the back-gate electrode; and
a gate dielectric film located between the second channel area and a first word line that is closer to the second channel area from among the pair of word lines,
wherein the back-gate dielectric film and the gate dielectric film are in contact with the superlattice layer.

12. A semiconductor memory device comprising:
a conductive line extending in a first direction;
a superlattice layer disposed on the conductive line;
a plurality of channel areas spaced apart from each other in the first direction, wherein the plurality of channel areas are spaced apart from the conductive line in a third direction;
a plurality of contact plugs spaced apart from the conductive line in the third direction, wherein the plurality of channel areas are respectively arranged between the plurality of contact plugs and the conductive line;
a back-gate electrode extending in a second direction between a first channel area and a second channel area of the plurality of channel areas, the first channel area and the second channel area being adjacent to each other, wherein the back-gate electrode is spaced apart from the conductive line in the third direction, and wherein the second direction is perpendicular to the first direction;
a back-gate dielectric film arranged between the back-gate electrode and the second channel area and contacting each of the back-gate electrode and the second channel area;
a word line spaced apart from the back-gate electrode in the first direction, wherein the second channel area is arranged between the word line and the back-gate electrode; and
a gate dielectric film arranged between the word line and the second channel area and contacting each of the word line and the second channel area,
wherein the superlattice layer has a structure in which a plurality of oxide layers and a plurality of compound layers are alternately stacked on each other.

13. The semiconductor memory device of claim 12, wherein the plurality of compound layers comprise silicon phosphide (SiP), and a concentration of phosphorus (P) included in the plurality of compound layers is in a range of about 10¹⁶/cm³ to about 10²²/cm³.

14. The semiconductor memory device of claim 12, wherein the plurality of compound layers comprise silicon arsenide (SiAs), and a concentration of arsenic (As) included in the plurality of compound layers is in a range of about 10¹⁶/cm³ to about 10²²/cm³.

15. The semiconductor memory device of claim 12, wherein a thickness of the superlattice layer in the third direction is in a range of about 1 nm to about 100 nm.

16. The semiconductor memory device of claim 12, wherein a concentration of oxygen atoms included in the plurality of oxide layers is in a range of about 10¹⁷/cm³ to about 10²²/cm³.

17. The semiconductor memory device of claim 12, further comprising a metal silicide film between the superlattice layer and the conductive line.

18. A semiconductor memory device comprising:
a plurality of conductive lines extending in a first direction and spaced apart from each other in a second direction that is perpendicular to the first direction;
a plurality of contact plugs spaced apart from the plurality of conductive lines in a third direction;
a plurality of channel areas respectively arranged between the plurality of conductive lines and the plurality of contact plugs, wherein each channel area of the plurality of channel areas comprises an end that is spaced apart from the plurality of conductive lines in the third direction and is connected to a contact plug of among the plurality of contact plugs;
a plurality of back-gate electrodes extending in the second direction between the plurality of conductive lines and the plurality of contact plugs and spaced apart from each other in the first direction;
a plurality of back-gate dielectric films respectively contacting the plurality of back-gate electrodes;
a plurality of word lines extending in the second direction between the plurality of conductive lines and the plurality of contact plugs;
a plurality of gate dielectric films respectively contacting the plurality of word lines; and
a superlattice layer arranged between the plurality of channel areas and the plurality of conductive lines,
wherein the superlattice layer has a structure in which a plurality of oxide layers and a plurality of compound layers are alternately stacked on each other, and
the plurality of compound layers comprise a material selected from among silicon phosphide (SiP), silicon arsenide (SiAs), and a combination of SiP and SiAs.

19. The semiconductor memory device of claim 18, wherein a thickness of the superlattice layer in the third direction is in a range of about 1 nm to about 100 nm.

20. The semiconductor memory device of claim 18, wherein a concentration of oxygen atoms included in the plurality of oxide layers is in a range of about 10¹⁷/cm³ to about 10²²/cm³.
